(19) United States
(12) Patent Application Publication
(10) Pub. No.: US 2008/0088337 A1
(43) Pub. Date: Apr. 17, 2008

(54) Apparatus for Inspecting a Display Device and Method for Inspecting the Display Device

(76) Inventors: Se-Chun Oh, Seongnam-si (KR); Jong-Kun Yoo, Seoul (KR)

Correspondence Address: Frank Chau, Esq.;F. CHAU & ASSOCIATES, LLC, 130 Woodbury Road, Woodbury, NY, 11797, US

(21) Appl. No.: 11/859,633

(22) Filed: Sep. 21, 2007

(30) Foreign Application Priority Data
Oct. 12, 2006 (KR) 2006-99117

(51) Int. Cl. G01R 31/00

(52) U.S. Cl. 324/770

(57) ABSTRACT

An apparatus for inspecting a display device includes an inspection substrate and a power supply part. The inspection substrate is electrically connected to a flexible circuit film that is connected to a display panel of the display device. The inspection substrate outputs inspection signals inspecting a connection between the display panel and the flexible circuit film. The power supply part is electrically connected to the inspection substrate. The power supply part provides driving power to the display panel. Thus, the inspection substrate is electrically connected to the flexible circuit film. Manufacturing costs for the apparatus may be reduced and the connection between the display panel and the flexible circuit film may be inspected.

### CROSS-REFERENCE TO RELATED APPLICATION

This application claims priority tinder 35 U.S.C. §119 to Korean Patent Application No. 10-2006-0099117, tiled on Oct. 12, 2006, in the Korean Intellectual Property Office (KIPO) the contents of which is hereby incorporated by reference in its entirely,

### BACKGROUND OF THE INVENTION

1. Technical Field

The present disclosure relates to a display device. More particularly, the present disclosure relates to an apparatus for inspecting a display device and a method for inspecting the display device.

2. Discussion of the Related Art

Generally, a liquid crystal display (LCD) apparatus includes an LCD panel to display images. The LCD panel includes a first substrate, a second substrate and a liquid crystal layer disposed between the first and second substrates. A thin film transistor (TFT) is formed on the first substrate, and a color filter is formed on the second substrate.

An electric driving signal is used to drive the TFT and the color filter. For example, the LCD panel includes a driving chip and a flexible circuit film. The driving chip is disposed on the first substrate to control the driving signal. The flexible circuit film is electrically connected to an edge of the first substrate to transfer the driving signal to the driving chip from an exterior. In this case, the flexible circuit film includes a plurality of driving lines, and the driving chip includes a plurality of input pins corresponding to the plurality of the driving lines.

An aging test is performed to inspect whether the LCD panel is normally driven for a predetermined time with a predetermined condition. Generally, in a conventional aging test, an aging mode is inserted into the driving chip and then a driving power is transferred to the flexible circuit film through an additional power connection line.

However, driving lines, except for the power connection line of the flexible circuit film, can not be inspected using the conventional aging test. Accordingly, a connection between the flexible circuit film and the LCD panel has decreased reliability.

### SUMMARY OF THE INVENTION

Exemplary embodiments of the present invention provide an apparatus for inspecting a display device capable of inspecting a connection between a flexible circuit film and a display panel.

Exemplary embodiments of the present invention also provide a method for inspecting the display device.

An apparatus for inspecting a display device, according to an exemplary embodiment of the present invention, includes an inspection substrate and a power supply part. The inspection substrate is electrically connected to a flexible circuit film that is connected to a display panel of the display device. The inspection substrate outputs inspection signals inspecting a connection between the display panel and the flexible circuit film. The power supply part is electrically connected to the inspection substrate, to provide driving power to the display panel.

The inspection substrate may include a logical element outputting a first inspection signal that is one of the inspection signals that are repeatedly reversed into a high signal or a low signal in every frame according to a polarity reverse signal outputted from the display panel. The inspection substrate may also include an inverter element reversing the first inspection signal outputted from the logical element to output a second inspection signal that is one of the inspection signals. The inspection substrate may also include first inspection lines transferring the first inspection signal outputted from the logical element to first driving lines. The first driving lines are odd-numbered lines of the flexible circuit film. Second inspection lines transfer the second inspection signal outputted from the inverter element to second driving lines. The second driving lines are even-numbered lines of the flexible circuit film.

The logical element may include a data flip-flop outputting the high signal when the polarity reverse signal is an anode, and outputting the low signal when the polarity reverse signal is a cathode.

The display device may further include a driving chip that is electrically connected to the display panel and has a signal inspection part inspecting the first and second inspection signals that are transferred from the first and second driving lines.

The signal inspection part may include a first logical circuit part and a second logical circuit part. The first logical circuit part may output a first result of the high signal when the inspection signals transferred from a first frame and a second frame are the same. The first logical circuit part may output a first result of the low signal when the inspection signals transferred from the first and second frames are different from each other. The first and second frames may continue from one of the first and second inspection signals. The second logical circuit part may be connected to the first logical circuit part. The second logical circuit part may output a second result of the high signal when all the first results are the high signals. The second logical circuit part may output a second result of the low signal when at least one first result is the low signal.

The signal inspection part may further include a delay part delaying one of the first and second inspection signals in the first frame into the second frame.

In addition, the first logical circuit part may include an EXCLUSIVE OR circuit, and the second logical circuit part may include an OR circuit.

The signal inspection part may include a first logical circuit part and a second logical circuit part. The first logical circuit part may output a first result of the high signal when the first and second inspection signals adjacent to each other are different from each other. The first logical circuit part may output a first result of the low signal when the first and second inspection signals adjacent to each other are the same. The second logical circuit part may be connected to the first logical circuit part. The second logical circuit part may output a second result of the high signal when all the first results are the high signals. The second logical circuit part may output a second result of the low signal when at least one first result is the low signal.

The driving chip may further include a panel driving part having an aging mode inside of the panel driving part. The aging mode may inspect the aging of the display device via the driving power. The apparatus may further include an inspection chamber receiving the display device to provide a closed space.

A method for inspecting the display device according to an exemplary embodiment of the present invention includes driving a display panel of the display device via a driving power from a power supply part to output a polarity reverse signal. The polarity reverse signal is transferred to an inspection substrate. A first inspection signal and a second inspection signal are output reversing the first inspection signal in the inspection substrate. The first inspection signal is transferred to first driving lines that are odd-numbered lines of a flexible circuit film through first inspection lines of the inspection substrate and the second inspection signal is transferred to second driving lines that are even-numbered lines of the flexible circuit film through second lines of the inspection substrate. The first and second inspection signals that are transferred to the first and second driving lines are transferred to a signal inspection part of a driving chip connected to the display panel. The first and second inspection signals in the signal inspection part are inspected to check a connection between the display panel and the flexible circuit film.

According to an exemplary embodiment of the present invention, the flexible circuit film includes the inspection substrate inside of the flexible circuit film. The driving chip of the display device includes the signal inspection part that inspects the first and second driving lines of the flexible circuit film inside of the driving chip so that the connection between the flexible circuit film and the display panel may be inspected.

### BRIEF DESCRIPTION OF THE DRAWINGS

The above and other features of the present disclosure will become more apparent by describing in detailed example embodiments of the present invention with reference to the accompanying drawings, in which:

FIG. 1 is a plan view illustrating an apparatus for inspecting a display device according to an exemplary embodiment of the present invention;

FIG. 2 is a cross-sectional view taken along a line I-I′ of FIG. 1;

FIG. 3 is an enlarged view showing a portion A in FIG. 1;

FIG. 4 is an enlarged view showing a portion B in FIG. 1;

FIG. 5 is a block diagram illustrating a driving process of the apparatus in FIG. 1 according to an exemplary embodiment of the present invention;

FIG. 6 is a block diagram illustrating a first logical circuit part and a second logical circuit part in FIG. 5;

FIG. 7 is a signal diagram illustrating signals of the apparatus in FIG. 5;

FIG. 8 is a block diagram illustrating a driving process of the apparatus in FIG. 1 according to an exemplary embodiment of the present invention;

FIG. 9 is a signal diagram illustrating signals of the apparatus in FIG. 8, and

FIG. 10 is a block diagram illustrating a method for inspecting a display device according to an exemplary embodiment of the present invention.

### DETAILED DESCRIPTION OF THE EXEMPLARY EMBODIMENTS

Exemplary embodiments of the invention are described more fully hereinafter with reference to the accompanying drawings. This invention may, however, be embodied in many different forms and should not he construed as limited to the exemplary embodiments set forth herein. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. Like numbers may refer to like elements throughout.

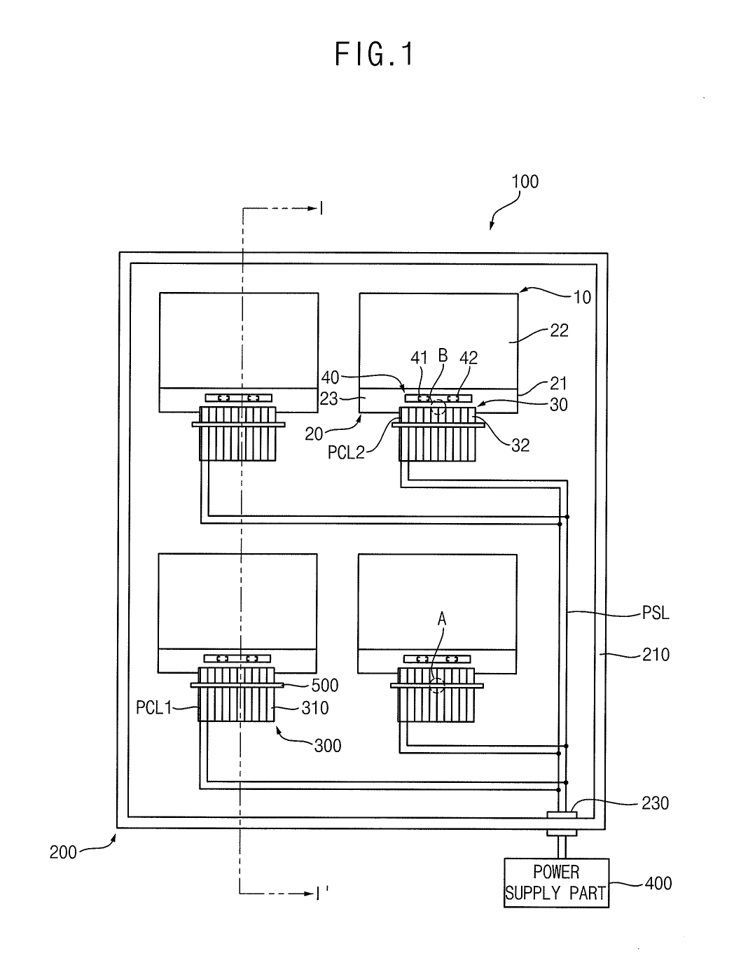

FIG. 1 is a plan view illustrating an apparatus 100 for inspecting a display device 10 according to an exemplary embodiment of the present invention. FIG, 2 is a cross-sectional view taken along a line I-I′ of FIG. 1.

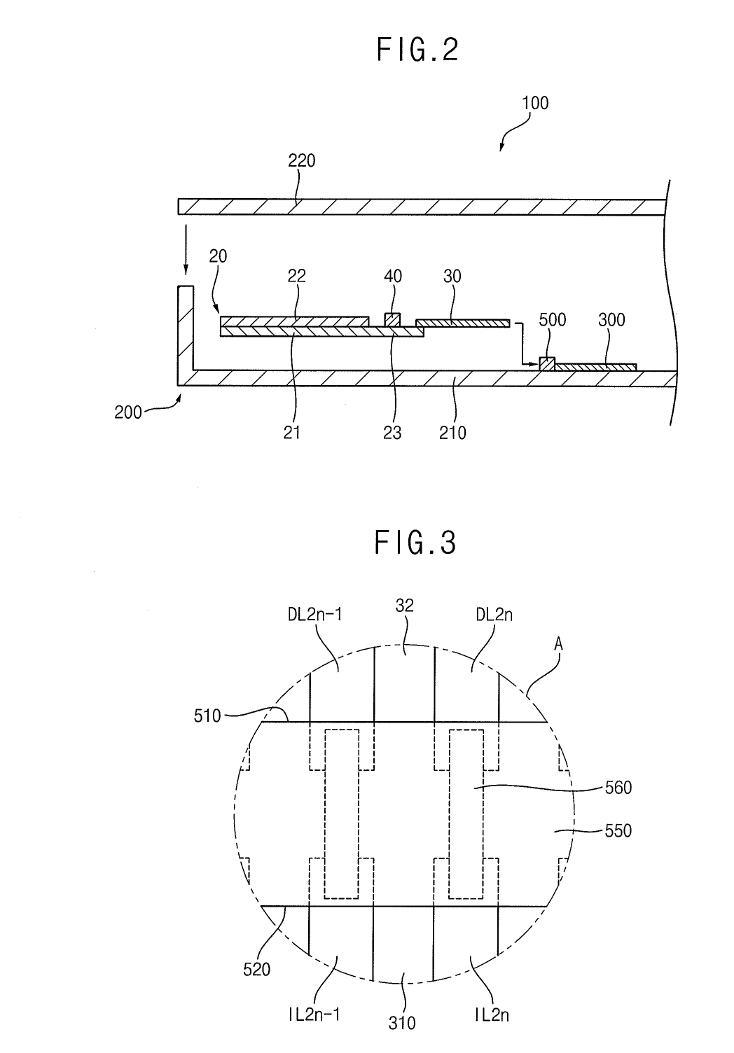

Referring to FIGS. 1 and 2, the apparatus 100 for inspecting the display device 10 includes an inspection chamber 200, an inspection substrate 300 and a power supply part 400.

The inspection chamber 200 receives the display device 10 and provides a closed space. For example, the inspection chamber 200 includes a receiving part 210 receiving the display device 10, and a cover pail 220 covering the receiving part 210. An additional sealing part may be formed at a contact position between the receiving part 210 and the cover part 220. A plurality of display devices may be received in the inspection chamber 200.

Stability of the display device 10 is tested in a predetermined condition, via the inspection chamber 200. The test is an aging test. For example, the aging test inspects whether the display device 10 is stable when driven at a temperature of about 60° C.

An inspection substrate 300 is electrically connected to a flexible circuit film 30 that is electrically connected to the display panel 20 of the display device 10. The inspection substrate 300 outputs inspection signals that inspect a connection between the display panel 20 and the flexible circuit film 30. The display panel 20 may include a first substrate 21, a second substrate 22 and a liquid crystal layer (not shown) disposed between the first and second substrates 21 and 22.

The first substrate 21 includes a thin film transistor (TFT) substrate on which a plurality of TFTs are arranged in a matrix. The second substrate 22 includes a color filter substrate on which a thin film color filter is formed. The display panel may include a backlight unit disposed on a surface of the display panel.

The first substrate 21 includes an extended portion 23 that is extended longer than the second substrate 22 at an edge of the first substrate 21. Thus, the flexible circuit film 30 is electrically connected to an edge of the extended portion 23. The inspection substrate 300 is electrically connected to the flexible circuit film through a connector 500.

For example, a first edge 510 (FIG. 3) of the connector 500 is electrically connected to the flexible circuit film 30, and a second edge 520 of the connector 500 opposite to the first edge 510 is electrically connected to the inspection substrate 300. The connector 500 may be fixed into the inspection chamber 200.

The connector 500 has a relatively larger width than that of the flexible, circuit film 30 and the inspection substrate 300. The connector 500 is properly adjusted to the size of the display device. A guide pin may be formed in the connector 500 to guide the width of various flexible circuit films 30 and inspection substrates 300. The connector 500 may include a transparent material to inspect the connection between the flexible circuit film 30 and the inspection substrate 300.

The inspection substrate 300 may be used by various display devices. The inspection substrate 300 may be fixed to the connector 500. The width of the inspection substrate 300 may correspond to the width of the widest flexible circuit film 30. Thus, the connector 500 is connected to the display device 10 that is to be inspected and the inspection may be simplified.

The display device 10 may further include a driving chip 40 on the extended portion 23 of the first substrate 21. The driving chip 40 outputs a driving signal that displays an image to the display panel 20. The driving signal is applied through the flexible circuit film 30. For example, the driving chip 40 is electrically connected to the flexible circuit film 30. The area of the extended portion 23 may be minimized.

The power supply part 400 is electrically connected to the inspection substrate 300 and driving power is supplied to the display panel 20. For example, the driving power is transferred to the display panel 20 through the flexible circuit film 30 connected by the inspection substrate 300 and the connector 500 and through the driving chip 40 connected to the flexible circuit film 30. First power connection lines PCL1, electrically connected to the power supply part 400, are formed on the inspection substrate 300. Second power connection lines PCL2, electrically connected to the first power connection lines PCL1, are formed on the flexible circuit film 30.

Generally, the power supply part 400 is disposed outside of the inspection chamber 200. The power supply part 400 is connected to the inspection substrate 300 through a power supply Sine PSL. The power supply line PSL is separated from the receiving part 210 or the cover part 220 of the inspection chamber 200.

For example, an additional power socket 230 is formed in the receiving part 210 or the cover part 220 and the separated power supply lines PSL are connected. Thus, it may he simple to change the power supply part 400 and the inspection chamber 200 may be strongly sealed. Alternatively, the power supply lines PSL may be directly connected to the inspection substrate 300.

A panel driving part 41 and a signal inspection part 42 including the aging mode is inserted into the driving chip 40. The aging mode is designed to test the aging of the display device 10 by the driving power from the power supply pan 400. In this case, a specific image need not be displayed in the aging test and driving power is transferred to the aging mode. The aging mode includes a basic driving pattern and a driving sequence.

The inspection part 42 inspects the inspection signals outputted from the inspection substrate 300 and decides whether the connection between the display panel 20 and the flexible circuit film 30 is normal. For example, the signal inspection part 42 inspects at least two inspection signals.

When the aging test is performed in the apparatus 100 for inspecting the display device 10, the inspection substrate 300 outputting the inspection signals is electrically connected to the flexible circuit film 30 and the signal inspection part 42 inspecting the inspection signals is inserted into the driving chip 40. Thus, the connection between the display panel 20 and the flexible circuit film 30 may be inspected.

Accordingly, the apparatus 100 for inspecting the display device 10 may ensure reliability of the aging test. In addition, only the connector 500 and the power supply part 400 need to be added to the apparatus 100 for inspecting the display device 10. The apparatus 100 may accordingly have a simple structure. Thus, manufacturing costs for the apparatus 100 may be reduced.

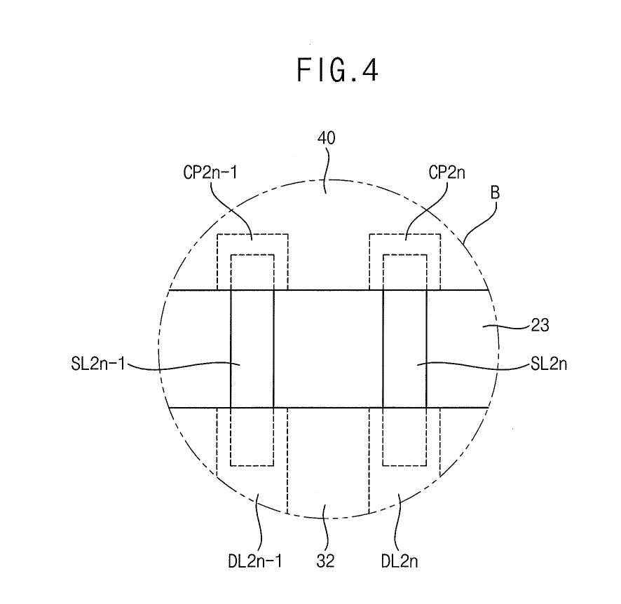

FIG. 3 is an enlarged view showing a portion A in FIG. 1. FIG. 4 is an enlarged view showing a portion B in FIG. 1.

Referring to FIGS. 1, 3 and 4, the inspection substrate 300 further includes first and second inspection lines IL2n-1 and IL2n on an insulating substrate 310. The flexible circuit film 30 further includes first and second driving lines DL2n-1 and DL2n on an insulating film 32. The first and second driving lines DL2n-1 and DL2n correspond to the first and second inspection lines IL2n-1 and IL2n, respectively.

The inspection signals outputted from the inspection substrate 300 are transferred to the first and second inspection lines IL2n-1 and IL2n. The first and second inspection lines IL2n-1 and IL2n are substantially parallel with each other and are sequentially formed on the inspection substrate 300.

For example, the first inspection lines IL2n-1 are formed at odd-numbered terminals and the second inspection lines IL2n are formed at even-numbered terminals, when viewed from an end terminal of the inspection substrate 300. The first driving lines DL2n-1 correspond to the odd-numbered terminals of the flexible circuit film 30 and the second driving lines DL2n correspond to the even-numbered terminals of the flexible circuit film 30.

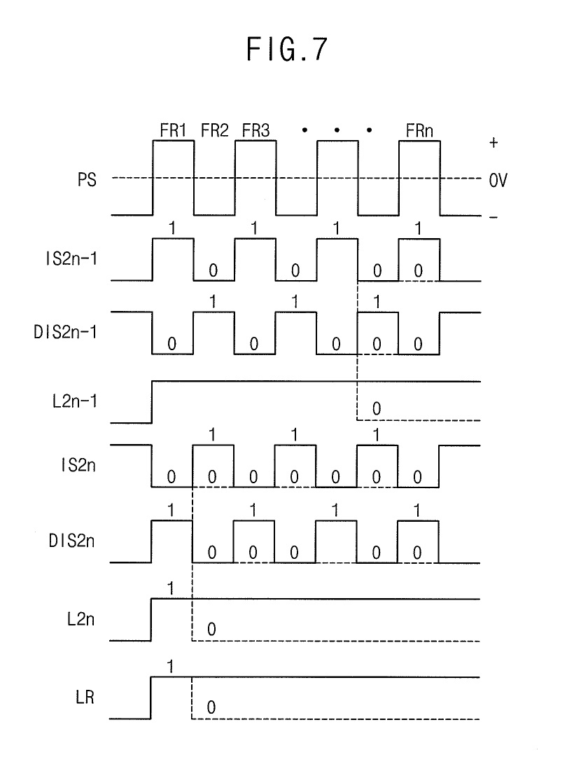

The inspection signals transferred to the inspection lines are reversed relative to each other, and the first and second inspection lines IL2n-1 and IL2n are divided. More detailed descriptions will he explained referring to FIG 7.

The connector 500 includes a connection body 550 and a connection socket 560. The connection body 550 is fixed to the inspection chamber 200. The connection socket 560 is formed in the connection body 550 and connects the first and second inspection lines IL2n-1 and IL2n with the first and second driving lines DL2n-1 and DL2n. The connection socket 560 preferably has a predetermined elasticity and holds the first and second inspection lines IL2n-1 and IL2n and the first and second driving lines DL2n-1 and DL2n more safely.

Alternatively, the connector 500 Sacks the connection socket 560 and holds the first and second inspection lines IL2n-1 and IL2n and the first and second driving lines DL2n-1 and DL2n. The first and second inspection lines IL2n-1 and IL2n may partially overlap the first and second driving lines DL2n-1 and DL2n. At least one of the first and second inspection lines IL2n-1 and IL2n and the first and second driving lines DL2n-1 and DL2n is extended to an opposite surface of the insulating substrate 310 or the insulating film 32. Accordingly, the overlapped portions between the first and second inspection lines IL2n-1 and IL2n correspond to the first and second inspection lines IL2n-1 and IL2n.

Thus, in the apparatus 100 for inspecting the display device 10 according to the present example embodiment, the first and second inspection lines IL2n-1 and IL2n formed on the inspection substrate 300, and the first and second driving lines DL2n-1 and DL2n formed on the flexible circuit film 30 may be simply connected to each other through the connector 500.

The driving chip 40 includes first and second connection pins CP2n-1 and CP2n that are electrically connected to the first and second driving lines DL2n-1 and DL 2n, respectively. The first and second connection pins CP2n-1 and CP2n are indirectly connected to the first and second driving lines DL2n-1 and DL2n through first and second substrate lines SL2n-1 and SL2n formed on the extended portion 23.

The first and second substrate lines SL2n-1 and SL2n may be electrically connected to the first and second driving lines DL2n-1 and DL2n through an anisotropic conductive film (ACF). The first and second connection pins CP2n-1 and CP2n may be electrically connected to the first and second substrate lines SL2n-1 and SL2n through the ACF. The first and second connection pins CP2n-1 and CP2n are electrically connected to the signal inspection part 42 inserted into the driving chip 40.

Thus, the inspection signals outputted from the inspection substrate 300 passes through the first and second inspection lines IL2n-1 and IL2n, the first and second driving lines DL2n-1 and DL2n, the first and second substrate lines SL2n-1 and SL2n, and the first and second connection pins CP2n-1 and CP2n, and are transferred to the signal inspection part 42 of the driving chip 40.

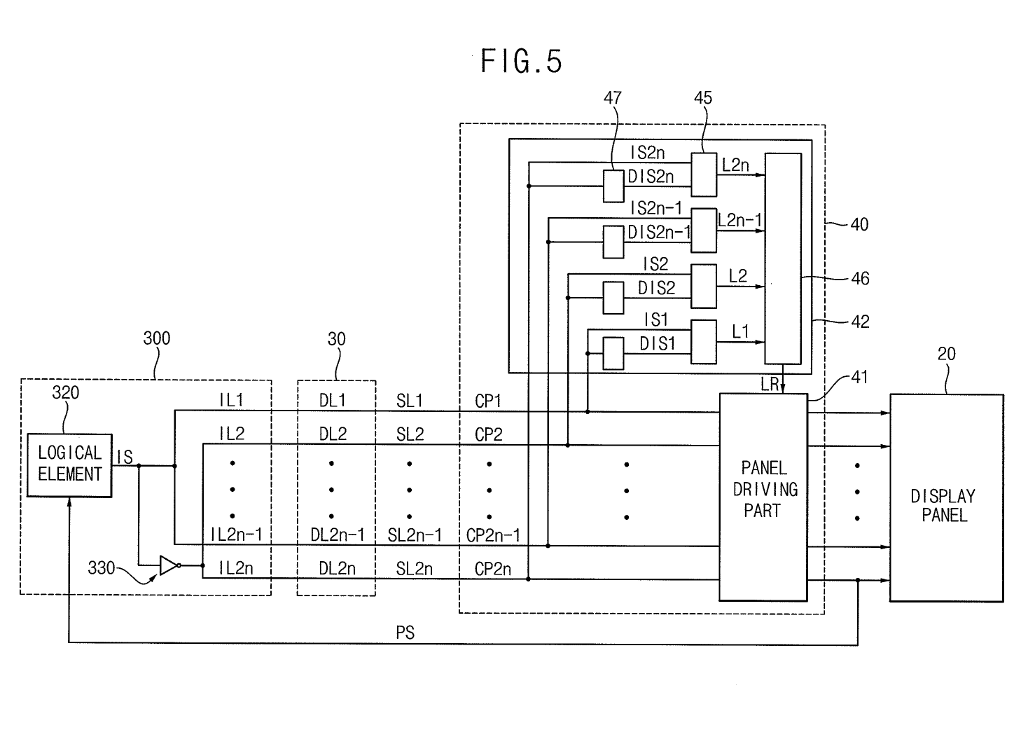

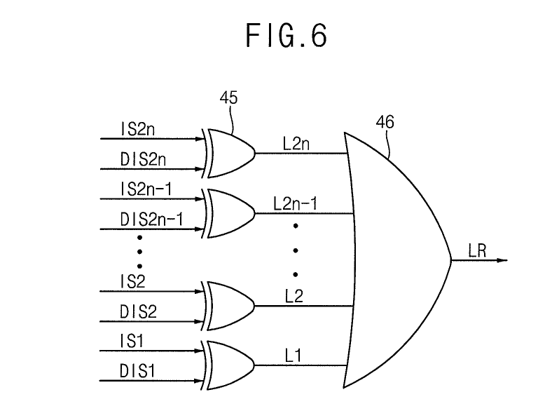

FIG. 5 is a block, diagram illustrating a driving process of the apparatus 100 in FIG. 1 according to an exemplary embodiment of the present invention. FIG. 6 is a block diagram illustrating a first logical circuit part and a second logical circuit part in FIG. 5. FIG. 7 is a signal diagram illustrating signals of the apparatus 100 in FIG. 5.

Referring to FIGS. 5, 6 and 7, the inspection substrate 300 includes a logical element 320 and an inverter element 330.

The logical element 320 outputs the inspection signals IS from a polarity reverse signal PS that is outputted from the display panel 20. Generally, the polarity reverse signal PS is repeatedly reversed to an anode and a cathode with respect to a reference voltage 0 V in each frame FR1, FR2, . . . FRn, to control heating of liquid crystal molecules of the liquid crystal layer. For example, the polarity reverse signal PS is a toggling signal.

Thus, the logical element 320 outputs a high signal “1,” when the polarity reverse signal PS indicates the cathode that is higher than the reference voltage 0 V. The logical element 320 outputs a low signal “0” when the polarity reverse signal PS indicates the anode that is lower than the reference voltage 0 V.

The high and low signals “1” and “0” are reversed contemporaneously with the polarity reverse signal PS, as the polarity reverse signal PS is repeatedly reversed. For example, the logical element 320 outputs the inspection signals IS that are toggled. For example, the logical element 320 may include a data flip flop.

The logical element 320 is directly connected to the first inspection lines IL2n-1. Accordingly, the inspection signal IS that is not changed is transferred to the first inspection lines IL2n-1. For example, the first inspection line IL2n-1 outputs the high signal “1” outputted from the logical element 320, when the polarity reverse signal indicates the cathode.

The inverter element 330 is disposed between the logical element 320 and the second inspection lines IL2n. The inverter element 330 reverses the inspection signal IS outputted from the logical element 320. Accordingly, the second inspection line IL2n outputs the low signal “0” as the high signal “1” outputted from the logical element 320 is reversed.

Accordingly, the inspection signals IS are transferred to the first and second inspection lines IL2n-1 and IL2n. In addition, the inspection signals IS are toggled in each frame FR1, FR2, . . . , FRn and are transferred to the first and second inspection lines IL2n-1 and IL2n, respectively.

Therefore, the first and second driving lines DL2n-1 and DL2n connected to the first and second inspection lines IL2n-1 and IL2n may be checked for short circuits. When the same inspection signals IS are transferred to the first and second driving lines DL2n-1 and DL2n, the same inspection signals IS are transferred through a short portion even in the event of a short circuit. Thus, the short circuit of the first and second driving lines DL2n-1 and DL2n may not be checked.

For convenience, the inspection signals IS transferred to the first and second inspection lines IL2n-1 and IL2n are explained by first inspection signals IS2n-1 and second inspection signals IS2n as explained below.

The first inspection signals IS2n-1 are transferred to the signal inspection part 42 inserted into the driving chip 40 through the first inspection lines IL2n-1, the first driving lines DL2n-1, the first substrate lines SL2n-1 and the first connection pins CP2n-1. The signal inspection part 42 includes a first logical circuit part 45 and a second logical circuit part 46.

The first logical circuit part 45 outputs the high signal “1” when two input signals are different from each other, and outputs primary first results L2n-1 of the low signal “0” when two input signals are the same. For example, the first logical circuit part 45 may include an EXCLUSIVE OR circuit. In the present exemplary embodiment, two input signals are generated from the first and second frames FRn-1 and FRn continuing from the first inspection signals IS2n-1.

For example, the signal inspection part 42 includes a delay part 47. The delay part 47 is connected to the first connection pin CP2n-1 in parallel, to delay the first inspection signal IS2n-1 in the first frame FRn-1 to the second frame FRn. In this case, the delayed first inspection signal IS2n-1 is indicated as a first delay inspection signal DIS2n-1 to distinguish the delayed first inspection signal IS2n-1 from an original signal. For example, the delay part 47 may include a memory latch.

Accordingly, the first inspection signal IS2n-1 and the first delay inspection signal DIS2n-1 are inputted to the first logical circuit 45, and the primary first results L2n-1 of the high signal “1” or the low signal “0” is outputted.

For example, when the first inspection signal IS2n-1 and the first delay inspection signal DIS2n-1, in which the high signal “1” and the low signal “0” are normally toggled, are inputted to the first logical circuit part 45, the primary first result L2n-1 of the high signal “1” is outputted.

However, when the first inspection lines IL2n-1 the first driving lines DL2n-1, the first substrate lines SL2n-1 and the first connection pin CP2n-1 to which the first inspection signal IS 2n-1 is transferred, have errors such as short circuits, the high signal “1” and the low signal “0” are not normally toggled, so that the primary first result L2n-1 of the low signal “0” is outputted. For example, when the first inspection lines IL2n-1, the first driving lines DL2n-1, the first substrate lines SL2n-1 and the first connection pin CP2n-1 have errors such as a line short circuit, the first inspection signals IS2n-1 always transfer the low signal “0” regardless of the frames FR1, FR2, . . . , FRn, so that the primary first result L2n-1 of the low signal “0” is outputted.

Accordingly, the connections of the first inspection lines IL2n-1, the first driving lines DL2n-1, the first substrate line SL2n-1 and the first connection pins CP2n-1 may be checked by inspecting whether the first inspection signals IS2n-1 are toggled in every frame FR1, FR2, . . . , FRn.

The second inspection signals IS2n are transferred to the signal inspection pan 42 inserted into the driving chip 40, through the second inspection lines IL2n, the second driving lines DL2n, the second substrate lines SL2n and the second connection pin CP2n. The signal inspection part 42 inspects the second inspection signals IS2n in the same way as in the first inspection signals IS2n-1, except that the second inspection signals IS2n are reversed in the same frame FR1, FR2, . . . , FRn as the first inspection signals IS2n-1. For example, when the first logic circuit part 45 inspects the second inspection signal IS2n, a secondary first result L2n is outputted.

The second logical circuit part 46 is connected to the first logical circuit part 45. The second logical circuit part 46 compares the primary and secondary first results L2n-1 and L2n, and outputs the second results LR of the high signal “1” or the low signal “0.” For example, the second logical circuit part 46 outputs the second result LR of the high signal “1” when the primary and secondary first results L2n-1 and L2n are the high signal “1.” However, the second logical circuit part 46 outputs the second result LR of the low signal “0” when at least one of the primary and secondary first results L2n-1 and L2n is the low signal “0.”

Thus, when at least one portion of the connection between the flexible circuit film 30 and the display panel 20 has an error such as a line short circuit, the second logical circuit part 46 outputs the second result LR of the low signal “0,” so that an inspector may discover the connection error.

For example, the second result LR is transferred to the panel driving pan 41, and turns the panel driving part 41 on or off according to the high signal “1,” or the low signal blocked. When the second result (LR) is the high signal “1,” the image is displayed in the display panel 20. When the second result (LR) is the Sow signal “0,” the image is blocked. Thus, the inspector may discover the connection error when the image is blocked in the display panel 20.

Accordingly, the first and second inspection signals IS2n-1 and IS2n are outputted by using the logical element 320 and the inverter element 330 formed on the inspection substrate 300. The first and second inspection signals IS2n-1 and IS2n are compared in the first and second logical circuit parts 45 and 46, so that the connection between the display panel 20 and the first and second driving lines DL2n-1 and DL2n of the flexible circuit film 30 may be inspected.

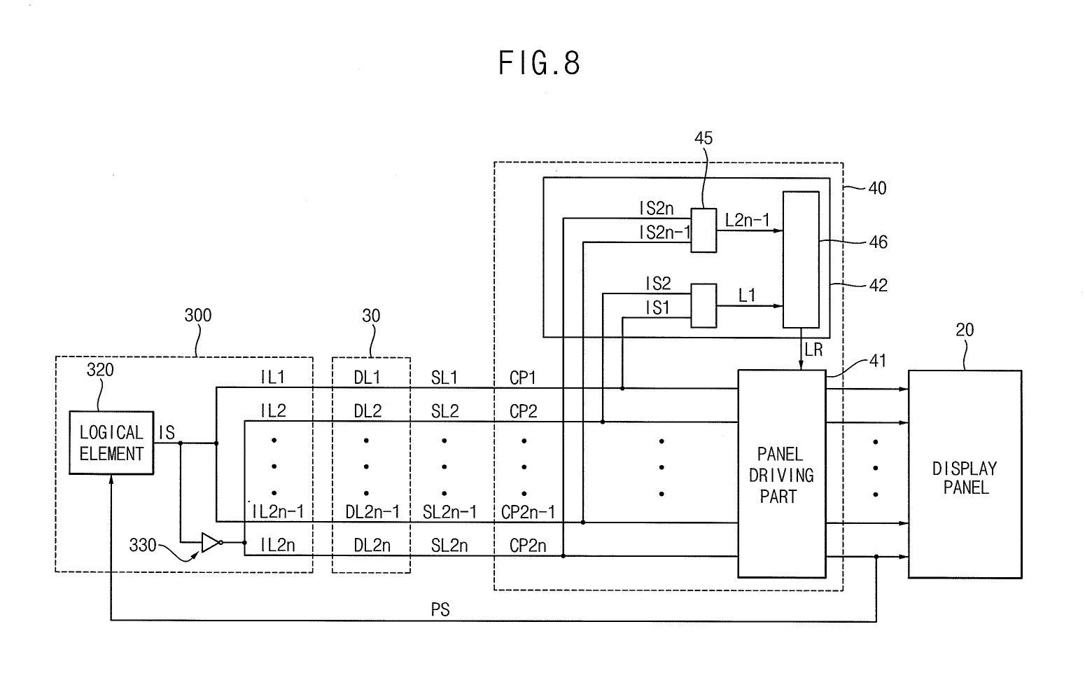

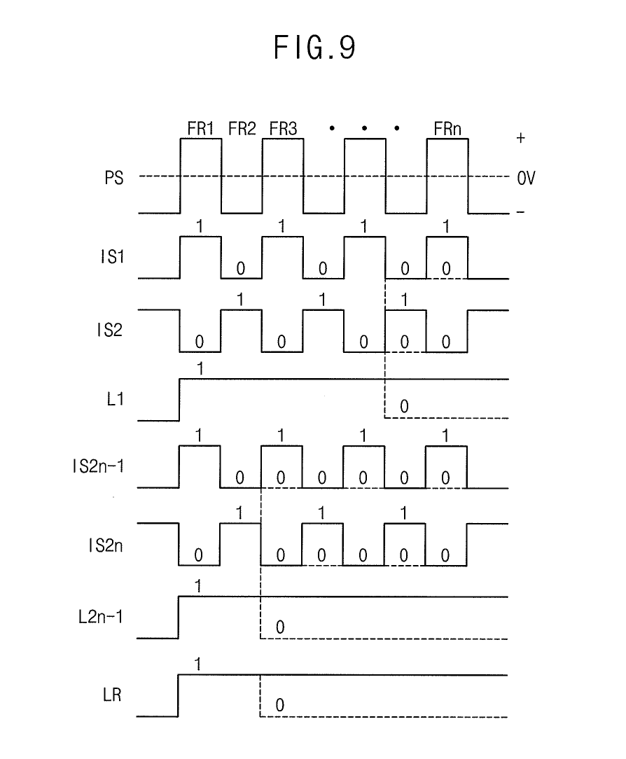

FIG. 8 is a block diagram illustrating a driving process of the apparatus 100 in FIG. 1 according to an exemplary embodiment of the present invention. FIG. 9 is a signal diagram illustrating signals of the apparatus 100 in FIG. 8.

The apparatus 100 for inspecting the display device 10 of the present exemplary embodiment is the same as in the exemplary embodiment illustrated in FIGS. 5, 6 and 7 except for two inspection signals inputted to the first logical circuit part formed on the signal inspection part of the driving chip. Thus, the same reference numerals may be used to refer to the same or like parts as those described in the previous exemplary embodiment.

Referring to FIGS. 1, 8 and 9, the first and second inspection signals IS2n-1 and IS2n, transferred from adjacent first and second inspection lines IL2n-1 and IL2n, are transferred to a first logical circuit part 45 of the signal inspection part 42 inserted into the driving chip 40 of the display device 10.

The first and second inspection signals IS2n-1 and IS2n are divided by the inverter element 330 formed on the inspection substrate 300. Accordingly, the first and second inspection signals IS2n-1 and IS2n are toggled with each other in the same frame FR1, FR2, . . . , FRn.

For example, when the first and second inspection signals IS2n-1 and IS2n are normally transferred, the first and second inspection signals IS2n-1 and IS2n are different from each other. The first logical circuit part 45 may then output the first results L2n-1 of the high signal “1.”

However, when at least one pair of the first and second inspection lines IL2n-1 and IL2n, the first and second driving lines DL2n-1 and DL2n, the first and second substrate lines SL2n-1 and SL2n, and the first and second connection pins CP2n-1 and CP2n have an error such as a line short circuit, the first and second inspection signals IS2n-1 and IS2n are the same. For example, the low signal “0” is continuously outputted from one of the first and second inspection signals IS2n-1 and IS2n. Thus, the first logical circuit part 45 outputs the first results L2n-1 of the low signal “0.”

The normal signal becomes the low signal “0” in the frames FR1, FR2, . . . , FRn-1 generating the low signal “0” when an error occurs in one of the first and second inspection signals IS2n-1 and IS2n. Accordingly, the low signal “0” may be outputted in the frames FR1, FR2, . . . , FRn-1 in which the error occurs or in the next frames FR2, FR3, . . . , FRn. For example, the normal signal is toggled to be converted into the high signal “1” in the next frames FR1, FR2, . . . , FRn, and the first results L2n-1 of the low signal “0” are outputted.

The second logical circuit part 46 outputs the second result LR of the high signal “1” when the first results L2n-1 are the high signal “1,” and outputs the second result LR of the low signal “0” when at least one first result L2n-1 is the low signal “0”. The connection between the display panel 20 and the flexible circuit film 30 is determined to be functional when the second result LR is the high signal “1” and the connection between the display panel 20 and the flexible circuit film 30 is determined to be inoperative when the second result LR is the low signal “0.”

Thus, the toggling state of the first and second inspection signals IS2n-1 and IS2n that are transferred from the first and second inspection lines IL2n-1 and IL2n is inspected in the same frame FR1, FR2, . . . , FRn Accordingly, the connection between the printed circuit film 30 and the display panel 20 may be checked.

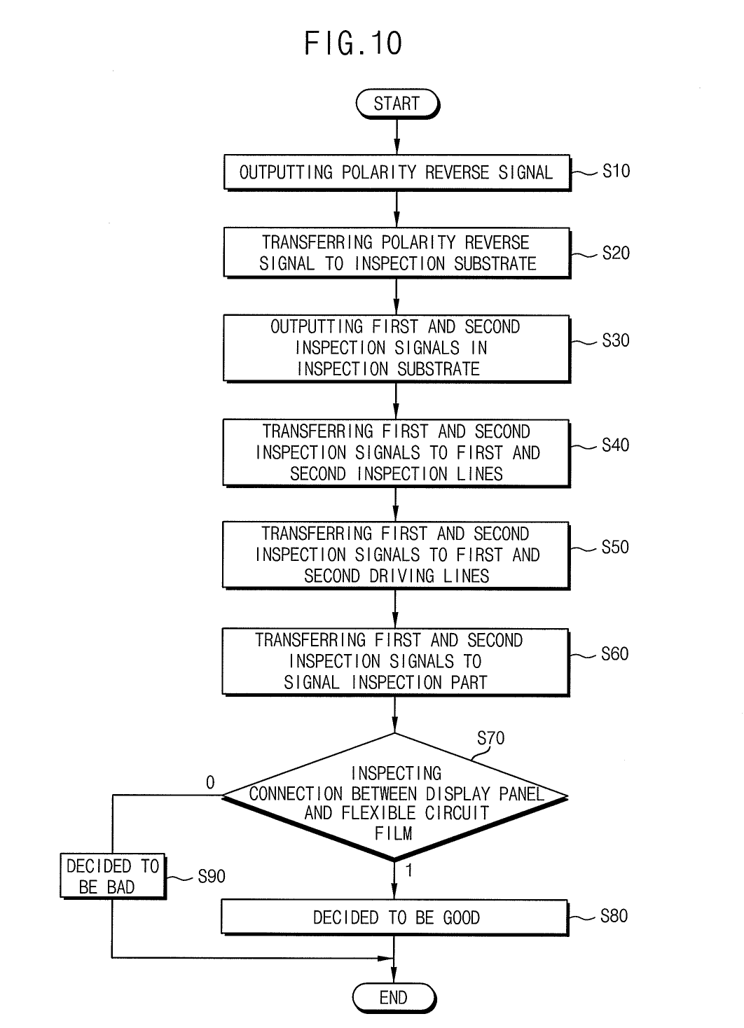

FIG. 10 is a block diagram illustrating a method for inspecting a display device 10 according to an exemplary embodiment of the present invention.

Referring to FIGS. 1, 8, 9 and 10, the display panel 20 of the display device 10 is driven by the driving power from the power supply part 400 and the polarity reverse signal PS is outputted (step S10). The polarity reverse signal PS reverses the polarity with respect to the reference voltage 0 V in every frame FR1, FR2, . . . , FRn.

Then, the polarity reverse signal PS is transferred to the inspection substrate 300 (step S20). For example, the polarity reverse signal PS is transferred to the logical element 320 of the inspection substrate 300. The logical element 320 outputs the high signal “1” when the polarity reverse signal PS is a cathode that is at a higher electrical potential than the reference voltage 0 V, and outputs the low signal “0” when the polarity reverse signal PS is an anode that is at a lower electrical potential than the reference voltage 0 V.

Then, the logical element 320 outputs the first inspection signal IS2n-1 through the polarity reverse signal PS. The inverter element 330, connected to the logical element 320, outputs the second inspection signal IS2n (step S30). The first and second inspection signals IS2n-1 and IS2n are reversed relative to each other.

Then, the first inspection signal IS2n-1 is transferred to the first inspection lines IL2n1 of the inspection substrate 300 and the second inspection signal IS2n is transferred to the second inspection lines IL2n of the inspection substrate 300 (step S40). The first inspection lines IL2n-1 are connected to the first driving lines DL2n-1 that are odd-numbered lines of the flexible circuit film 30. The second inspection lines IL2n are connected to the second driving lines DL2n that are even-numbered lines of the flexible circuit, film 30. For example, the first and second inspection signals IS2n-1 and IS2n are respectively transferred to the first and second driving lines DL2n-1 and DL2n (step S50).

Then, the first and second inspection signals IS2n-1 and IS2n, that are transferred to the first and second driving lines DL2n-1 and DL2n, are transferred to the signal inspection part 42 through the first and second connection pins CP2n-1 and CP2n of the driving chip 40 connected to the display panel 20 (step S60).

Finally, the first and second inspection signals IS2n-1 and IS2n are inspected in the signal inspection part 42, to decide the connection between the display panel 20 and the flexible circuit film 30 (step S70).

For example, the first results L2n-1 of the high signal “1” is outputted in the signal inspection part 42 when the inspection signals transferred from the first and second frames FRn-1 and FRn continuing from one of the first and second inspection signals IS2n-1 and IS2n are different from each other. The first results L2n-1 of the low signal “0” is outputted in the signal inspection part 42 when the inspection signals transferred from the first and second frames FRn-1 and FRn continuing from one of the first and second inspection signals IS2n-1 and IS2n are the same. In addition, the second result LR of the high signal “1” is outputted when all of the first results L2n-1 are the high signals “1.” The second result LR of the low signal “0” is outputted when at least one first result L2n-1 is the low signal “0.”

In this case, when the second result LR is the high signal “1,” the connection between the display panel 20 and the flexible circuit film 30 is determined to be functional (step S80). When the second result LR is the low signal “0,” the connection between the display panel 20 and the flexible circuit film 30 is determined to be inoperative (step S90).

Alternatively, adjacent first and second inspection signals IS2n-1 and IS2n may be inspected.

According to an exemplary embodiment of the present invention, the inspection substrate transferring the inspection signal is electrically connected to the flexible circuit film in the aging test. The signal inspection part, inspecting the inspecting signal is inserted into the driving chip and the connection between the display panel and the flexible circuit film may be inspected. Thus, the reliability of the aging test may be ensured.

In addition, the connector and the power supply part are added to the inspection substrate and accordingly, the apparatus for inspecting the display device may have simple structures. Thus, total manufacturing costs may be reduced.

While the present disclosure has been particularly shown and described with reference to exemplary embodiments of the present invention, it will be understood by those of ordinary skill in the art that various changes in form and details may be made without departing from the spirit and scope of the present invention.

What is claimed is:

1. An apparatus for inspecting a display device, the apparatus comprising:
an inspection substrate, electrically connected to a flexible circuit film that is connected to a display panel of the display device, outputting a plurality of inspection signals for inspecting a connection between the display panel and the flexible circuit film; and
a power supply part electrically connected to the inspection substrate, providing driving power to the display panel.

2. The apparatus of claim 1, wherein the inspection substrate comprises:
a logical element outputting a first inspection signal that is one of the plurality of inspection signals, each of the plurality of inspection signals repeatedly switching between a high signal and a low signal in each frame according to a polarity reverse signal outputted from the display panel;
an inverter element switching the first inspection signal outputted from the logical element, to output a second inspection signal that is one of the plurality of inspection signals;
one or more first inspection lines transferring the first inspection signal outputted from the logical element to one or more first driving lines that are odd-numbered lines of the flexible circuit film; and
one or more second inspection lines transferring the second inspection signal outputted from the inverter element to one or more second driving lines that are even-numbered lines of the flexible circuit film.

3. The apparatus of claim 2, wherein the logical element comprises a data flip-flop outputting the high signal when the polarity reverse signal is an anode, and outputting the low signal when the polarity reverse signal is a cathode.

4. The apparatus of claim 2, wherein the display device further comprises a driving chip that is electrically connected to the display panel and has a signal inspection part inspecting the first and second inspection signals that are transferred from the first and second driving lines.

5. The apparatus of claim 4, wherein the signal inspection pail comprises:
a first logical circuit part, outputting a first result of the high signal when the inspection signals transferred from a first frame and a second frame are equal to each other, and outputting a first result of the low signal when the inspection signals transferred from the first and second frames are different from each other, the first and second frames continuing from one of the first and second inspection signals; and
a second logical circuit part connected to the first logical circuit part, the second logical circuit part outputting a second result of the high signal when each the first results are the high signals, and outputting a second result of the low signal, when at least one first result is the low signal.

6. The apparatus of claim 5, wherein the signal inspection part further comprises a delay part delaying one of the first and second inspection signals in the first frame to the second frame.

7. The apparatus of claim 6, wherein the first logical circuit part comprises an EXCLUSIVE OR circuit, and the second logical circuit part includes an OR circuit.

8. The apparatus of claim 4, wherein the signal inspection part comprises:
a first logical circuit part, outputting a first result of the high signal when the first and second inspection signals adjacent to each other are different from each other, and outputting a first result of the low signal when the first and second inspection signals adjacent to each other are equal to each other; and
a second logical circuit part connected to the first logical circuit part, the second logical circuit part outputting a second result of the high signal when each of the first results are the high signals, and outputting a second result of the low signal when at least one first result is the low signal.

9. The apparatus of claim 4, wherein the driving chip further comprises a panel driving part comprising an aging mode inside of the panel driving part inspecting the aging of the display device via the driving power.

10. The apparatus of claim 9, further comprising an inspection chamber receiving the display device and providing a closed space.

11. A method for inspecting a display device, the method comprising:
driving a display panel of the display device to output a polarity reverse signal, wherein a driving power driving the display panel is supplied by a power supply part;
transferring the polarity reverse signal to an inspection substrate;
outputting a first inspection signal and a second inspection signal, that is the reverse of the first inspection signal, in the inspection substrate;
transferring the first inspection signal to one or more first driving lines that are odd-numbered lines of a flexible circuit film through first inspection lines of the inspection substrate, and transferring the second inspection signal to one or more second driving lines that are even-numbered lines of the flexible circuit film through second lines of the inspection substrate;
transferring the first and second inspection signals that are transferred to the first and second driving lines to a signal inspection part of a driving chip connected to the display panel; and
inspecting the first and second inspection signals in the signal inspection part, to check a connection between the display panel and the flexible circuit film.

12. The method of claim 11, wherein inspecting the first and second inspection signals comprises:
outputting a first result of a high signal when the inspection signals transferred from a first frame and a second frame are different from each other, and outputting a first result of a low signal when the inspection signals transferred from the first and second frames are equal to each other, the first and second frames continuing from one of the first and second inspection signals; and
outputting a second result of the high signal when each of the first results are the high signals, and outputting a second result of the low signal when at least one first result is the low signal.

13. The method of claim 12, wherein the connection between the display panel and the flexible circuit film is determined to be functional when the second result is the high signal, and the connection between the display panel and the flexible circuit film is determined to be inoperative when the second result is the low signal.

14. The method of claim 11, wherein inspecting the first and second inspection signals comprises:
outputting a first result of a high signal when the first and second inspection signals adjacent to each other are different from each other, and outputting a first result of a low signal when the first and second inspection signals adjacent to each other are equal to each other; and
outputting a second result, of the high signal when each of the first results are the high signals, and outputting a second result of the low signal when at least one first result is the low signal.
